(19) United States
(12) Patent Application Publication
(10) Pub. No.: US 2019/0334000 A1
(43) Pub. Date: Oct. 31, 2019

(54) Transistor Component

(71) Applicant: Infineon Technologies AG, Neubiberg (DE)

(72) Inventors: Markus Zundel, Egmating (DE); Karl-Heinz Bach, Groebenzell (DE); Peter Brandl, Finkenstein (AT); Franz Hirler, Isen (DE); Andrew Christopher Graeme Wood, St. Jakob im Rosenal (AT)

(21) Appl. No.: 16/393,051

(22) Filed: Apr. 24, 2019

(30) Foreign Application Priority Data
Apr. 25, 2018 (DE) 102018109950.9

(51) Int. Cl. H01L 29/40; H01L 29/06; H01L 29/10; H01L 29/08; H01L 29/423; H01L 29/36; H01L 29/78

(52) U.S. Cl. CPC H01L 29/407; H01L 29/0696; H01L 29/1095; H01L 29/0865; H01L 29/0882; H01L 29/7396; H01L 29/36; H01L 29/42376; H01L 29/7813; H01L 29/7811; H01L 29/4236

(57) ABSTRACT

A transistor component includes at least one transistor cell having: a drift region, a source region, a body region and a drain region in a semiconductor body, the body region being arranged between the source and drift regions, and the drift region being arranged between the body and drain regions; a gate electrode arranged adjacent to the body region and dielectrically isolated from the body region by a gate dielectric; and a field electrode arranged adjacent to the drift region and dielectrically isolated from the drift region by a field electrode dielectric. The field electrode dielectric has a thickness that increases in a direction toward the drain region. The drift region has, in a mesa region adjacent to the field electrode, a doping concentration that increases in the direction toward the drain region.

### TECHNICAL FIELD

The present description relates to a transistor component, in particular a transistor component comprising a field electrode.

### BACKGROUND

Transistor components comprising a field electrode, which are often also referred to as field plate transistors, are in widespread use as electronic switches in various applications such as, for example, automotive, industrial, consumer electronics or domestic electronics applications. In this type of transistor component, the field electrode is arranged adjacent to a drift region and serves, when the transistor component is in the off state, to “compensate” for a portion of the dopant atoms present in the drift region. On account of this compensation effect there is the possibility of doping the drift region more highly than in conventional transistor components without a field electrode, without the dielectric strength of the component being reduced. As a result, a reduced on resistance is achieved for the same dielectric strength or a higher dielectric strength is achieved for the same on resistance.

There is a need to further reduce the on resistance of a transistor component of this type.

### SUMMARY

One example relates to a transistor component. The transistor component comprises at least one transistor cell comprising: a drift region, a source region, a body region and a drain region in a semiconductor body, wherein the body region is arranged between the source region and the drift region, and the drift region is arranged between the body region and the drain region; a gate electrode, which is arranged adjacent to the body region and is dielectrically isolated from the body region by a gate dielectric; and a field electrode, which is arranged adjacent to the drift region and is dielectrically isolated from the drift region by a field electrode dielectric. The field electrode dielectric has a thickness that increases in a direction toward the drain region, and the drift region has, in a mesa region adjacent to the field electrode, a doping concentration that increases in the direction toward the drain region.

### BRIEF DESCRIPTION OF THE FIGS

Examples are explained below with reference to drawings. The drawings serve to illustrate specific principles, and so only features necessary for understanding these principles are illustrated. The drawings are not true to scale. In the drawings, identical reference signs designate identical features.

FIG. 1 shows as an excerpt a cross section of a transistor component comprising a plurality of transistor cells, each comprising a field electrode arranged adjacent to a drift region;

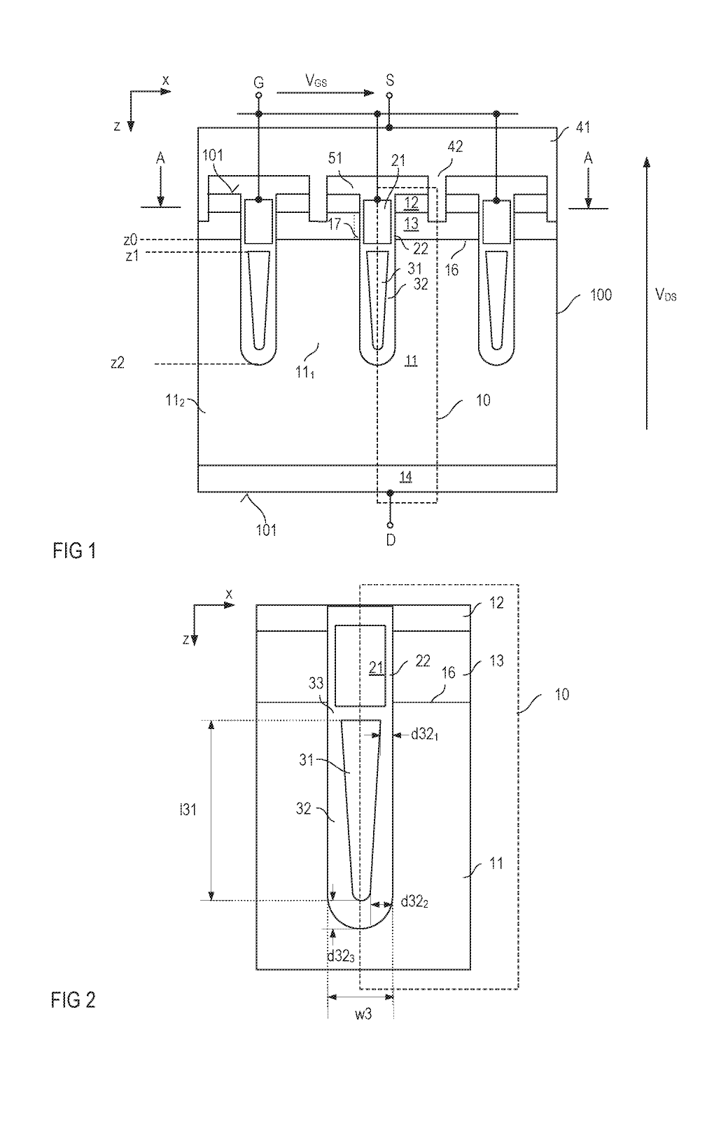

FIG. 2 shows an enlarged excerpt from the transistor component shown in FIG. 1:

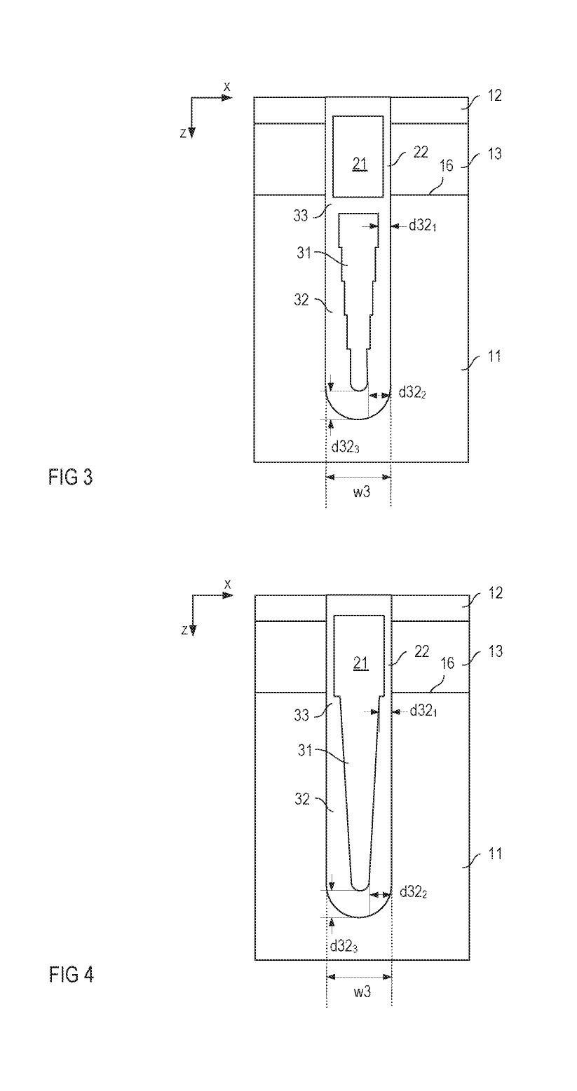

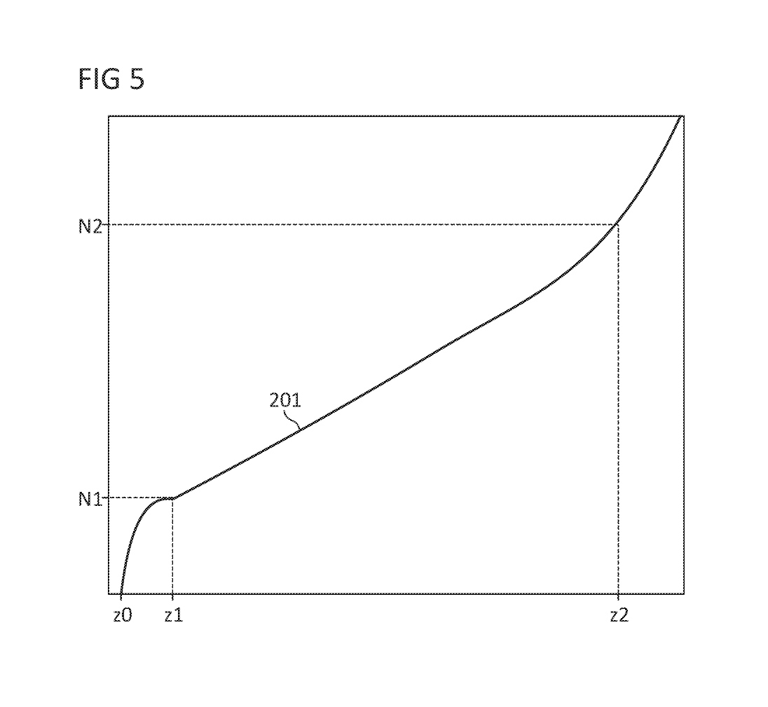

FIGS. 3 and 4 each show further examples of a field electrode;

FIG. 5 illustrates one example of a doping profile of the drift region in a current flow direction of the transistor component;

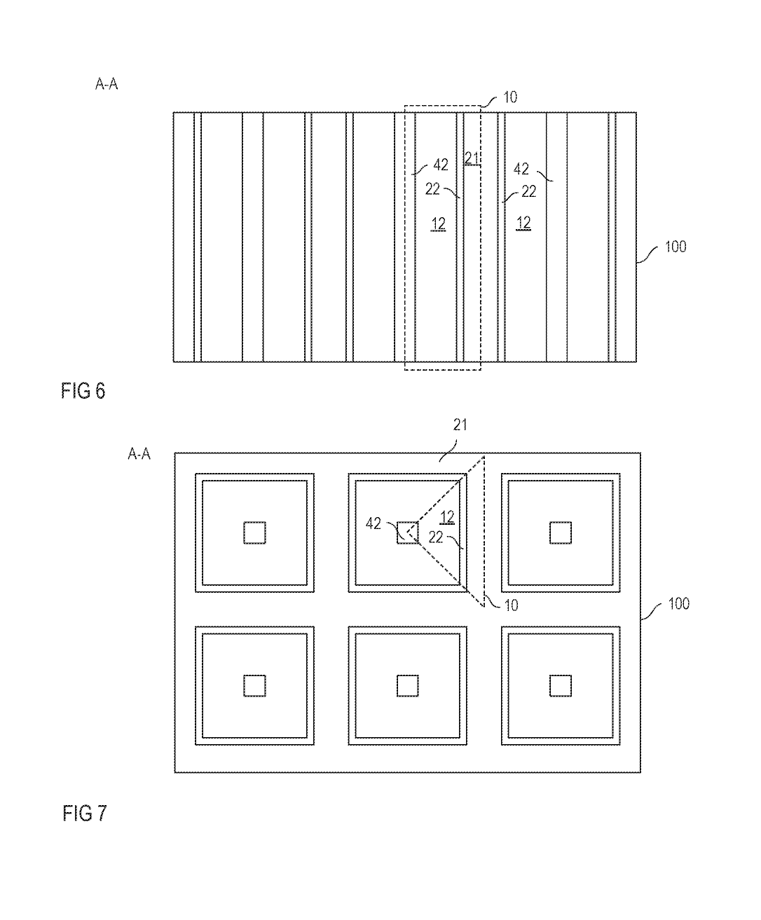

FIG. 6 shows one example for realizing a plurality of transistor cells:

FIG. 7 shows a further example for realizing a plurality of transistor cells;

FIG. 8 shows one example of how a gate electrode can be connected to a gate runner;

FIG. 9 shows one example of how a field electrode can be connected to a source electrode;

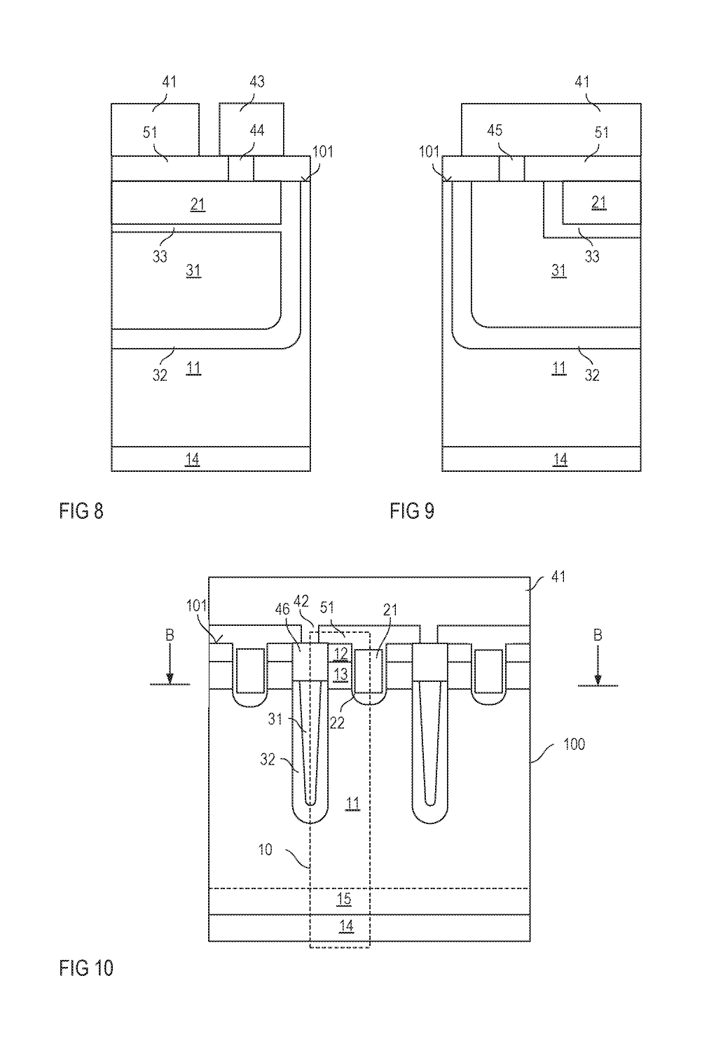

FIG. 10 shows a sectional illustration of a transistor component in accordance with a further example; and

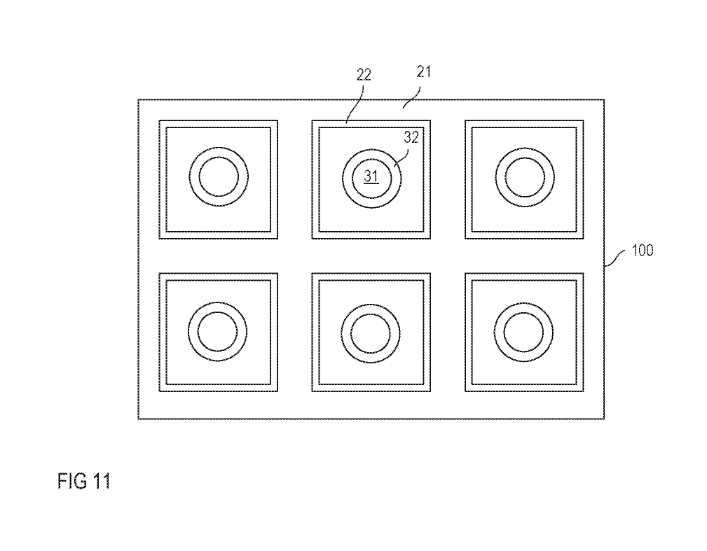

FIG. 11 shows one example of how a plurality of transistor cells can be realized in the case of a transistor component such as the transistor component shown in FIG. 10.

### DETAILED DESCRIPTION

In the following description, reference is made to the accompanying drawings, which form part of the description. It goes without saying that the features of the individual drawings can be combined with one another, unless indicated otherwise.

FIG. 1 shows a sectional illustration of a transistor component in accordance with one example. This transistor component comprises at least one transistor cell 10, wherein a plurality of transistor cells 10 are illustrated in the example. Said transistor cells each comprise a drift region 11, a source region 12, a body region 13, and a drain region 14 in a semiconductor body 100. In this case, the body region 13 is arranged between the source region 12 and the drift region 11, and the drift region 11 is arranged between the body region 13 and the drain region 14. Each transistor cell 10 additionally comprises a gate electrode 21, which is arranged adjacent to the body region 13 and which is dielectrically isolated from the body region 13 by a gate dielectric 22. Moreover, each transistor cell 10 comprises a field electrode 31, which is arranged adjacent to the drift region 11 and which is dielectrically isolated from the drift region by a field electrode dielectric 32. The field electrode dielectric 32 has a thickness that increases in a direction toward the direction of the drain region 14. That is to say that there are one or more sections of the field electrode dielectric 32 in which the thickness of the field electrode dielectric 32, which thickness defines a distance between the field electrode 31 and the drift region 11, increases in the direction toward the drain region 14. Moreover, the drift region 11 has, in a mesa region 11₁ adjacent to the field electrode 31, a doping concentration that increases in the direction toward the drain region 14. This increase in the doping concentration of the drift region 11 is explained in more detail further below.

The term “transistor cell” denotes one of a plurality of structures of identical type in the transistor component, each of which comprises a drift region 11, a source region 12, a body region 13, a gate electrode 21, a gate dielectric 22, a field electrode 31 and a field electrode dielectric 32. In this case, by way of example, the drain region 14 of all the transistor cells 10 can be formed by a continuous doped region, which is also referred to hereinafter as common drain region and which is connected to a drain terminal D (which is only illustrated schematically in FIG. 1) of the transistor component. The drift regions 11 of the individual transistor cells 10 can be formed by a continuous doped region, which is also referred to hereinafter as common drift region. Furthermore, the source regions 12 of two or more adjacent transistor cells can be formed by a common doped region, the body regions 12 of two or more adjacent transistor cells can be formed by a common doped region, the gate electrodes 21 of two or more adjacent transistor cells 21 can be formed by a common electrode, and the field electrodes 31 of two or more transistor cells 10 can be formed by a common electrode.

Referring to FIG. 1, the transistor component can be realized as a vertical transistor component. In this case, the source regions 12 and the drain regions 14 of the individual transistor cells 10 are arranged at a distance from one another in a vertical direction z of the semiconductor body 100. The “vertical direction” of the semiconductor body 100 is a direction perpendicular to a first side 101 and to a second side 102 of the semiconductor body, said second side being situated opposite the first side 101. In the example shown in FIG. 1, the source regions 12 adjoin the first side 101 of the semiconductor body 100 and the drain region adjoins the second side 102 of the semiconductor body. A current flow direction extends in the vertical direction z of the semiconductor body 100 in the case of a vertical transistor component.

Even though FIG. 1 shows a vertical transistor component, it should be pointed out that the transistor component is not restricted to being realized as a vertical transistor component. The configurations explained below of the field electrode 31, of the field electrode dielectric and of the doping profile of the drift region 11 apply to a lateral transistor component, in which source regions and drain regions of individual transistor cells are arranged at a distance from one another in a lateral (horizontal) direction of a semiconductor body in a corresponding manner.

The semiconductor body 100 is for example a monocrystalline semiconductor body composed of silicon (Si), silicon carbide (SiC), gallium arsenide (GaAs), gallium nitride (GaN) or the like. The gate electrodes 21 of the individual transistor cells 10 consist for example of a doped polycrystalline semiconductor material, such as polysilicon, for example, or a metal. The field electrodes 31 consist for example of a doped polycrystalline semiconductor material, such as polysilicon, for example, or of a metal.

The gate electrodes 21 of the individual transistor cells 10 are connected to a common gate terminal G. Said gate terminal G is only illustrated schematically in FIG. 1. Electrically conductive connections between the individual gate electrodes 21 and the gate terminal G are also only illustrated schematically in FIG. 1. The source regions 12 and body regions 13 of the individual transistor cells 10 are connected to a common source terminal S. Referring to FIG. 1, for this purpose a source electrode 41 can be provided, which is connected to the source regions 12 and body regions 13 of the individual transistor cells 10 and which is connected to the source terminal S or forms said source terminal S. Said source electrode 41 is isolated from the gate electrodes 21 by isolation regions 51. In the case of the example shown in FIG. 1, the source electrode 41 has contact plugs 42, which, proceeding from the first side 101, extend through the source regions 12 right into the body regions 13 and are electrically conductively connected to the source regions 12 and the body regions 13. In accordance with one example, a respective ohmic contact is present between the contact plugs 42 and the source regions 12 and the body regions 13. It should be mentioned that the provision of contact plugs 42 such as are shown in FIG. 1 is merely one of a number of possibilities for connecting source regions 12 and body regions 13 of a plurality of transistor cells to a source electrode.

In accordance with one example, the field electrodes 31 of the individual transistor cells are connected to the source terminal S of the transistor component. In accordance with a further example, the field electrodes 31 are connected to the gate terminal G of the transistor component. Examples in respect thereof are explained further below.

In the individual transistor cells 10, the source region 12 and the drift region 11 are of the same conduction type or doping type (n-type or p-type), which is referred to hereinafter as first doping type, and the body region 13 is of a doping type complementary to the first doping type, this complementary doping type being referred to hereinafter as second doping type. On account of the complementary doping types of the body region 13 and the drift region 11, a pn junction 16 is formed between the body region 13 and the drift region 11. The transistor component can be realized as an n-conducting transistor component or as a p-conducting transistor component. In the case of an n-conducting transistor component, the source region 12 and the drift region 11 are n-doped and the body region 13 is p-doped; in the case of a p-conducting transistor component, the source region 12 and the drift region 11 are p-doped and the body region 13 is n-doped. Moreover, the transistor component can be realized as a normally off component (enhancement-mode component) or as a normally on component (depletion-mode component). In the case of a normally off component, the body region 13 directly adjoins the gate dielectric 22, while in the case of a normally on component, a channel region 17 (which is illustrated in a dotted manner only for one transistor cell in FIG. 1) of the same doping type as the source region 12 and the drift region 11 is present. Said channel region 17 extends along the gate dielectric 22 from the source region 12 as far as the drift region 11 and is arranged between the body region 13 and the gate dielectric 22. Furthermore, the transistor component can be realized as a MOSFET (Metal Oxide Semiconductor Field-Effect Transistor) or as an IGBT (Insulated Gate Bipolar Transistor). In the case of a MOSFET, the drain region 14 has the same doping type as the source region 12, while in the case of an IGBT, the drain region 14 (which can also be referred to as collector region) has a doping type complementary to the source region 12.

The functioning of a transistor component of the type shown in FIG. 1 is briefly explained below. It shall be assumed for explanation purposes that the transistor component is an n-conducting MOSFET, that is to say that the source region 12, the drift region 11 and the drain region 14 are n-doped and the body region 13 is p-doped. The transistor component is in the on state or in the off state depending on a control voltage V_{GS} present between the gate terminal G and the source terminal S, which control voltage can also be referred to as gate-source voltage. The transistor component is in the on state if said control voltage V_{GS} is higher than a threshold voltage of the transistor component, such that, in the case of a normally off component, a conducting channel forms in the body region 13 along the gate dielectric 22 between the source region 12 and the drift region 13 or, in the case of a normally on component, the channel region 17 is not interrupted. If a load path voltage V_{DS}, which can also be referred to as drain-source voltage, not equal to zero is present between the drain terminal D and the source terminal S, a current flows between the drain terminal D and the source terminal S when the transistor component is in the on state.

If, when the transistor component is in the off state, a load path voltage V_{DS} is present which is greater than zero and which is polarized such that it reverse-biases the pn junction 16 between the drift region 11 and the body region 13, a space charge zone (depletion zone) propagates in the drift region 11 proceeding from the pn junction 16 in the direction of the drain region 14. (A corresponding space charge zone also propagates in the body region 13. However, the body region 13 is usually more highly doped than the drift region 11, such that the space charge zone in the body region 13 proceeding from the pn junction 16 does not extend as far into the body region 13 as the space charge zone in the drift region 11.) The space charge zone propagating in the drift region 11 is associated with ionized dopant atoms, which are positively charged donor cores in the case of an n-doped drift region 11. Said positively charged donor cores have corresponding counter-charges in the body region 13, which are negatively charged acceptors in the case of a p-doped body region 13, or the field electrode 31. A voltage breakdown at the pn junction occurs if, on both sides of the pn junction, the number of dopant atoms ionized is of a magnitude such that an electric field at the pn junction 16 reaches a critical value which is crucially dependent on the type of semiconductor material used for the semiconductor body 100. The dielectric strength of the transistor component is defined by the voltage level of the load path voltage V_{DS} at which the electric field strength at the pn junction reaches the critical value.

Since, in the case of a transistor component of the type shown in FIG. 1, in which the individual transistor cells 10 comprise field electrodes 31, some of the ionized dopant atoms in the drift region 11 find a corresponding counter-charge in the field electrode 31, the drift region 11 can be more highly doped than in the case of a transistor component without a field electrode, without reducing the dielectric strength of the transistor component. However, a higher doping of the drift region 11 reduces the on resistance of the transistor component, which is fundamentally desirable. The “on resistance” is the electrical resistance between the drain terminal D and the source terminal S when the transistor component is driven in the on state.

The above-explained compensation effect of the field electrode 31 is all the better, the better the field electrode 31 is capacitively coupled to the drift region 11, that is to say the thinner the field electrode dielectric 32. On the other hand, the field electrode dielectric 32 must be able to withstand the potential difference (the voltage) between the electrical potential and the drift region 11 and the electrical potential of the field electrode 31 when the transistor component is in the off state. It can be assumed that the field electrode 31 is uniformly at the same potential, which is source potential or gate potential, that is to say the electrical potential of the source terminal S or the electrical potential of the gate terminal G. When the component is in the off state, the electrical potential in the drift region 11 increases, proceeding from the pn junction 16, in the direction of the drain region 14. The voltage loading of the field electrode dielectric 32 thus increases in the current flow direction of the component. As a result of the thickness of the field electrode dielectric 32 that increases in the current flow direction, the field electrode dielectric 32 is able to withstand this voltage loading, but can be comparatively thin in the region near the pn junction 16, where the voltage loading is low, with the result that a better compensation effect can be achieved there than further in the direction of the drain region 14, where the field electrode dielectric 32 is correspondingly thicker. Where an improved compensation effect is achieved on account of the thin field electrode dielectric 32, there the drift region 11 can be more highly doped than in the case of a component in which the field electrode dielectric 32 has a uniform thickness, as a result of which a reduction of the on resistance can be achieved.

In order to explain the varying thickness of the field electrode dielectric 32, FIG. 2 shows an enlarged excerpt from the transistor component shown in FIG. 1. In association with the transistor component explained, the “thickness” of the field electrode dielectric 32 should be understood to mean, in particular, a thickness of the field electrode dielectric 32 between the field electrode 31 and a region 11₁ of the drift region 11 that adjoins the field electrode dielectric 32 in a direction x transverse to the current flow direction. Said region 11₁ is referred to hereinafter as mesa region. In the case of the vertical transistor component shown in FIG. 1, the direction x transverse to the current flow direction is a horizontal or lateral direction of the semiconductor body 10X), and thus a direction parallel to the first and second sides 101, 102 of the semiconductor body 100. The field electrode dielectric 32 has a minimum thickness d32₁ and a maximum thickness d32₂. In the case of the example shown in FIG. 2, the field electrode dielectric 32 has its minimum thickness d32₁ in the region of a first end of the field electrode 31 and its maximum thickness d32₂ in the region of a second end of the field electrode 31, said second end facing away from the first end. The “first end” of the field electrode 31 is the end arranged nearest to the pn junction 16; the “second end” is the end arranged nearest to the drain region 14. In accordance with one example, the maximum thickness d32₂ is at least 1.2 times, at least 1.4 times, at least 1.7 times, at least 2 to 5 times or at least 10 times the minimum thickness d32₁. The absolute value of the minimum thickness and of the maximum thickness is in each case dependent on the type of material of the field electrode dielectric 32 and the expected voltage loading. The field electrode dielectric 32 comprises for example at least one of the following materials: an oxide, such as silicon oxide (SiO₂), for example; a nitride, such as silicon nitride (Si₃N₄), for example; an oxynitride. In accordance with one example, the field electrode dielectric 32 comprises only one of these materials. In accordance with a further example, the field electrode dielectric 32 comprises two or more of these materials. In this regard, the field electrode dielectric 32 can comprise for example a plurality of layers arranged one above another, wherein two layers adjoining one another in each case comprise different materials.

The field electrode 31 has a length 131 in the current flow direction. In the case of the example shown in FIG. 2, in which the field electrode dielectric 32 has its minimum thickness d32₁ at the first end and its maximum thickness d32₂ at the second end of the field electrode 31, the distance between the position at which the field electrode dielectric 32 has the minimum thickness d32₁ and the position at which the field electrode dielectric 32 has the maximum thickness d32₂ is substantially given by said length 131. This is only one example, however. In accordance with a further example, provision is made for a distance between the position with the minimum thickness and the position with the maximum thickness in the current flow direction of the transistor component to be at least 30% of the length 131, at least 50% of the length 131, at least 70% of the length 131 or at least 90% of the length 131 of the field electrode 31.

In the case of the example shown in FIG. 2, the thickness of the field electrode dielectric 32 increases continuously in the current flow direction proceeding from a position at which the first end of the field electrode 31 is situated through to a position at which the second end of the field electrode 31 is situated. This is likewise only one example. In accordance with a further example shown in FIG. 3, provision is made for the thickness of the field electrode dielectric 32 to increase in a stepwise manner in the current flow direction. In this case, too, it holds true, for example, that a distance between the position with the minimum thickness and the position with the maximum thickness in the current flow direction of the transistor component is at least 50% of the length 131, at least 70% of the length 131 or at least 90% of the length 131 of the field electrode 31.

As explained above, the thickness of the field electrode dielectric that increases in the current flow direction is the thickness of the field electrode dielectric 32 in a region of the field electrode dielectric 32 between the field electrode 31 and the mesa region 11₁. A thickness d32₃ of the field electrode dielectric 32 between the field electrode 31 and a section 11₂ of the drift region 11 that is arranged between the field electrode dielectric 32 and the drain region 14 in the current flow direction, in accordance with one example, is equal to the maximum thickness d32₂ or greater than said maximum thickness, that is to say d32₃≥d32₂.

In the examples shown in FIGS. 2 and 3, the gate electrode 21 and the field electrode 31 are realized in each case in a common trench extending into the semiconductor body 100 proceeding from the first side 101. Within the common trench, the gate electrode 21 and the field electrode 31 are dielectrically isolated from one another by a dielectric layer 33. Said dielectric layer 33 can consist of the same material as the field electrode dielectric 32. On account of this isolated arrangement of the gate electrode 21 and the field electrode 31, the gate electrode 21 and the field electrode 31 can be at different electrical potentials. In this regard, the gate electrode 21 can be connected to the gate terminal G, for example, and the field electrode 31 can be connected to the source terminal S, for example. In accordance with one example, provision is made for a mutual distance between two adjacent trenches to be significantly less than the length 131 of the field electrodes 31 in the current flow direction. In accordance with one example, said distance is less than 25% or less than 10% of a length 131 of the field electrodes.

Hereinafter, w3 denotes a maximum width of a trench in which a field electrode and an associated field electrode dielectric are arranged. In accordance with a further example, with regard to the mutual distance between two of said trenches that are adjacent, provision is made for the mutual distance to be less than 1.5 times the trench width w3 or to be even less than the trench width w3 (that is to say less than 1.0 times the trench width w3).

FIG. 4 shows a further example of a field electrode 31. In the case of this example, the field electrode 31 and the gate electrode 21 are realized by a common electrode, such that the field electrode 31 is at the gate potential in the case of this example. In the case of the example shown in FIG. 4, the field electrode 31 has a geometry such as has been explained with reference to FIG. 2. This is only one example, however. It goes without saying that the field electrode 31 shown in FIG. 4 can also be realized with a stepped geometry as shown in FIG. 3.

As mentioned above, the doping concentration of the drift region 11 in the mesa region 11₁ increases in the direction of the drain region 14. In particular, the doping concentration increases in a section of the mesa region 11₁ which is adjacent to the field electrode 31 in the horizontal direction x. One exemplary doping profile of the doping concentration of the drift region 11 in the mesa region 11₁ is illustrated in FIG. 5. In FIG. 5, the curve designated by 201 shows the doping profile of the mesa region 11₁ between the pn junction, which, referring to FIG. 1, is situated at a position z0 in the current flow direction, and that end of the field electrode dielectric 32 which faces in the direction of the drain region 14 and which, referring to FIG. 1, is situated at a position z2 in the current flow direction.

FIG. 5 illustrates the effective doping concentration of the drift region 11. Directly at the pn junction 16, the effective doping concentration of the drift region 11 is very low and initially rises rapidly in the direction of the drain region 14. This is governed by the nature of the pn junction 16.

In addition to the rise—governed by the pn junction—in the doping concentration of the drift region 11 in the direction of the drain region 14, the doping concentration within the mesa region 11₁ rises even further, however, which is illustrated starting from the vertical position z1 in FIG. 5. Said position z1 corresponds for example to the vertical position at which the field electrode 31 begins, which is illustrated in FIG. 1, or still lies below said position proceeding from the front side 101. There is thus a section of the mesa region 11₁ which lies adjacent to the field electrode in the horizontal direction x and in which the effective doping concentration rises in the direction of the drain region 14. In accordance with one example, provision is made for the doping concentration of the drift region 11 in the mesa region 11₁ to rise at least over a distance in the current flow direction which corresponds to 50% of the length, 80% of the length or 95% of the length of the mesa region 11₁ in the current flow direction. The “length” of the mesa region 11₁ is given by the distance between the pn junction 16 and that end of the field electrode dielectric 32 which faces the drain region 14. In accordance with one example, a maximum doping concentration N2 of the mesa region 11₁ is between 2 times and 10 times a minimum doping concentration N1. In accordance with one example, the minimum doping concentration N1 is between 5E15 cm⁻³ and 1E17 cm⁻³.

In accordance with one example, provision is made for the doping of the drift region 11 to rise further in the region 11₂ between the mesa region and the drain region 14 in the current flow direction. In accordance with one example, a maximum doping concentration of the mesa region in the region 11₂, is between 2 times and 10 times a minimum doping concentration in said region 11₂.

In a plane A-A extending perpendicular to the sectional plane shown in FIG. 1, the individual transistor cells 10 can be realized in various ways. FIG. 6 shows one example, in which the individual transistor cells 10 are realized as strip cells. In the case of this example, the source regions 12 (and also the underlying body regions 13, which are outside the illustration in FIG. 6) are realized as elongated (strip-shaped) regions. The gate electrodes 21 are correspondingly realized as elongated (strip-shaped) electrodes. The same applies to the field electrodes 31, which are outside the illustration in FIG. 6.

FIG. 7 shows a further example for realizing the transistor cells 10. In the case of this example, the gate electrodes 21 of the individual transistor cells are realized by a common grid-shaped electrode. The source regions 12 (and the underlying body regions 13, which are outside the illustration in FIG. 7) are insular regions lying in cutouts of the grid-shaped gate electrode 21.

FIG. 8 shows one example of how an elongated gate electrode of the type shown in FIG. 6 or a grid-shaped gate electrode of the type shown in FIG. 7 can be connected to the gate terminal G. FIG. 8 shows a sectional view of the gate electrode 21 in the region of a horizontal end, wherein said horizontal end can be the end of an elongated gate electrode 21 or the end of a grid-shaped gate electrode 21. Referring to FIG. 8, the transistor component comprises a gate runner 43 adjacent to the source electrode 41 and above the isolation layer 51. The gate electrode 21 is connected to the gate runner 43 by means of an electrically conductive via 44 extending through the isolation layer 51. The gate runner 43 forms the gate terminal G or is connected to the gate terminal G of the transistor component.

FIG. 9 shows one example of how a field electrode 31 arranged below the gate electrode 21 in the same trench as the gate electrode 21 can be connected to the source electrode 41. In the case of this example, the field electrode 31 has a section which extends adjacent to the gate electrode 21 as far as the front side 101 of the semiconductor body and is connected there to the source electrode 41 by means of an electrically conductive via 45. In the case of a strip-shaped gate electrode 21 and a strip-shaped field electrode 31, the region in which the field electrode 31 is connected to the source electrode 41 can be situated at an end of the trench which is located opposite the end of the trench at which the gate electrode 21 is connected to the gate runner 43. In the case of a grid-shaped gate electrode 21 and a grid-shaped field electrode 31, the field electrode 31 can be connected to the source electrode 41 at an arbitrary end of the “grid” which is different from the end or ends at which the gate electrode 21 is connected to the gate runner 43.

In the case of the examples explained above, the field electrode 31 and the gate electrode 21 are arranged in a common trench of the semiconductor body. This is only one example, however. FIG. 10 shows a further example of a transistor component comprising a plurality of transistor cells 10, each comprising a field electrode. In the case of this example, the field electrodes 31 are arranged in trenches which are at a distance from trenches having the gate electrodes 21. In the case of this example, the field electrodes 31 are connected to the source electrode 41 by means of electrically conductive vias 46, wherein the electrically conductive via 46 simultaneously serves to connect the source regions 12 and the body regions 13 to the source electrode 41. With regard to the geometry of the field electrode 31 and the variation of the thickness of the field electrode dielectric 32, the statements made above in respect of the field electrode 31 and the field electrode dielectric 32 are correspondingly applicable.

In the example shown in FIG. 10, the gate electrodes 21 and the field electrodes 31 can be realized in each case in strip-shaped fashion. FIG. 11 shows a further example. In the case of this example, the gate electrodes 21 of the individual transistor cells are realized by a common grid-shaped electrode 21. The field electrodes 31 are columnar electrodes in this example. Merely for illustration purposes, these columns have a circular cross section in the example shown in FIG. 11. However, arbitrary other polygonal cross sections can likewise be realized.

Without being restricted thereto, the following numbered examples illustrate one or more aspects of the present description.

### Example 1

a transistor component comprising a transistor cell comprising: a drift region, a source region, a body region and a drain region in a semiconductor body, wherein the body region is arranged between the source region and the drift region, and the drift region is arranged between the body region and the drain region; a gate electrode, which is arranged adjacent to the body region and is dielectrically isolated from the body region by a gate dielectric; and a field electrode, which is arranged adjacent to the drift region and is dielectrically isolated from the drift region by a field electrode dielectric, wherein the field electrode dielectric has a thickness that increases in a direction toward the drain region, and wherein the drift region has, in a mesa region adjacent to the field electrode, a doping concentration that increases in the direction toward the drain region.

### Example 2

the transistor component according to example 1, wherein a ratio between a maximum thickness and a minimum thickness of the field electrode dielectric is at least 1.2, at least 1.4, at least 1.7 or at least between 2 and 5, or at least 10.

### Example 3

the transistor component according to an arbitrary combination of examples 1 to 17, wherein the thickness of the field electrode dielectric increases continuously.

### Example 4

the transistor component according to an arbitrary combination of examples 1 to 3, wherein the thickness of the field electrode dielectric increases in a stepwise manner.

### Example 5

the transistor component according to an arbitrary combination of examples 1 to 4, wherein a ratio between a maximum doping concentration and a minimum doping concentration in the mesa region adjacent to the field electrode is at least 2.

### Example 6

the transistor component according to an arbitrary combination of examples 1 to 5, wherein the doping concentration of the drift region in the mesa region increases over at least 30%, at least 50%, at least 70% or at least 90% of a length of the drift region in a current flow direction of the transistor component.

### Example 7

the transistor component according to an arbitrary combination of examples 1 to 6, wherein the field electrode and the field electrode dielectric are at a distance from the drain region in a current flow direction of the transistor component, wherein the doping concentration of the drift region in a section between the field electrode dielectric and the drain region increases in the direction of the drain region.

### Example 8

the transistor component according to an arbitrary combination of examples 1 to 7, wherein the source region and the field electrode are connected to the source terminal.

### Example 9

the transistor component according to an arbitrary combination of examples 1 to 8, wherein the gate electrode and the field electrode are connected to a gate terminal.

### Example 10

the transistor component according to an arbitrary combination of examples 1 to 9, wherein the gate electrode and the field electrode are arranged in a common trench in the semiconductor body.

### Example 11

the transistor component according to an arbitrary combination of examples 1 to 10, wherein the transistor component comprises a plurality of transistor cells, wherein the gate electrodes of the plurality of transistor cells are formed by first strip-shaped electrodes, and wherein the field electrodes of the plurality of transistor cells are formed by second strip-shaped electrodes.

### Example 12

the transistor component according to an arbitrary combination of examples 1 to 11, wherein the transistor component comprises a plurality of transistor cells, wherein the gate electrodes of the plurality of transistor cells form a common grid-shaped electrode, and wherein field electrodes of the plurality of transistor cells form a common grid-shaped electrode.

### Example 13

the transistor component according to an arbitrary combination of examples 1 to 12, wherein the gate electrode and the field electrode are arranged in separate trenches in the semiconductor body.

### Example 14

the transistor component according to an arbitrary combination of examples 1 to 13, wherein the transistor component comprises a plurality of transistor cells, wherein the gate electrodes of the plurality of transistor cells are formed by a common grid-shaped electrode, and wherein the field electrodes of the plurality of transistor cells are formed in each case by columnar electrodes.

The examples explained above serve merely to illustrate how the invention can be implemented. It goes without saying that various modifications and combinations of these examples and also other examples are possible.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor component comprising at least one transistor cell comprising:
a drift region, a source region, a body region and a drain region in a semiconductor body, the body region being arranged between the source region and the drift region, the drift region being arranged between the body region and the drain region;
a gate electrode arranged adjacent to the body region and dielectrically isolated from the body region by a gate dielectric; and
a field electrode arranged adjacent to the drift region and dielectrically isolated from the drift region by a field electrode dielectric,
wherein the field electrode dielectric has a thickness that increases in a direction toward the drain region,
wherein the drift region has, in a mesa region adjacent to the field electrode, a doping concentration that increases in the direction toward the drain region.

2. The transistor component of claim 1, wherein a ratio between a maximum thickness and a minimum thickness of the field electrode dielectric is at least 1.2.

3. The transistor component of claim 1, wherein a ratio between a maximum thickness and a minimum thickness of the field electrode dielectric is between 2 and 5.

4. The transistor component of claim 1, wherein a ratio between a maximum thickness and a minimum thickness of the field electrode dielectric is at least 10.

5. The transistor component of claim 1, wherein the thickness of the field electrode dielectric increases continuously.

6. The transistor component of claim 1, wherein the thickness of the field electrode dielectric increases in a stepwise manner.

7. The transistor component of claim 1, wherein a ratio between a maximum doping concentration and a minimum doping concentration in the mesa region adjacent to the field electrode is at least 2.

8. The transistor component of claim 1, wherein the doping concentration of the drift region in the mesa region increases over at least 30% of a length of the drift region in a current flow direction of the transistor component.

9. The transistor component of claim 1, wherein the doping concentration of the drift region in the mesa region increases over at least 50% of a length of the drift region in a current flow direction of the transistor component.

10. The transistor component of claim 1, wherein the doping concentration of the drift region in the mesa region increases over at least 70% of a length of the drift region in a current flow direction of the transistor component.

11. The transistor component of claim 1, wherein the doping concentration of the drift region in the mesa region increases over at least 90% of a length of the drift region in a current flow direction of the transistor component.

12. The transistor component of claim 1, wherein the field electrode and the field electrode dielectric are at a distance from the drain region in a current flow direction of the transistor component, and wherein the doping concentration of the drift region in a section between the field electrode dielectric and the drain region increases in the direction of the drain region.

13. The transistor component of claim 1, wherein the source region and the field electrode are connected to a source terminal.

14. The transistor component of claim 1, wherein the gate electrode and the field electrode are connected to a gate terminal of the transistor component.

15. The transistor component of claim 1, wherein the gate electrode and the field electrode are arranged in a common trench in the semiconductor body.

16. The transistor component of claim 15, wherein the transistor component comprises a plurality of transistor cells, wherein the gate electrode of each transistor cell is formed by a first strip-shaped electrode, and wherein the field electrode of each transistor cell is formed by a second strip-shaped electrode.

17. The transistor component of claim 15, wherein the transistor component comprises a plurality of transistor cells, wherein the gate electrodes of the plurality of transistor cells form a common grid-shaped electrode, and wherein field electrodes of the plurality of transistor cells form a common grid-shaped electrode.

18. The transistor component of claim 15, wherein the transistor component comprises a plurality of transistor cells, wherein the gate electrodes of the plurality of transistor cells are formed by a common grid-shaped electrode, and wherein the field electrode of each transistor cell is formed by a columnar electrode.

19. The transistor component of claim 1, wherein the gate electrode and the field electrode are arranged in separate trenches in the semiconductor body.
